(19) United States
(12) Patent Application Publication
(10) Pub. No.: US 2018/0035556 A1
(43) Pub. Date: Feb. 1, 2018

(54) Angle Setters For Modular Display System

(71) Applicant: ACASS Systems LLC, Omaha, NE (US)

(72) Inventor: Aaron D. Cass, Omaha, NE (US)

(21) Appl. No.: 15/649,166

(22) Filed: Jul. 13, 2017

Related U.S. Application Data
(60) Provisional application No. 62/361,831, filed on Jul. 13, 2016.

(51) Int. Cl. H05K 5/00; G06F 3/14; H05K 5/02

(52) U.S. Cl. CPC H05K 5/0017; H05K 5/0021; H05K 5/0208; H05K 5/0217; G06F 3/1446

(57) ABSTRACT

An angle setter secured to respective surfaces of two or more modular units of a modular display system helps to provide or enable a predetermined overall angle or a predetermined overall amount of curvature for the modular display system. The angle setter has a predetermined angle proportional to a separation angle between the two or more modular units, to a radius of curvature, or proportional to a center angle of a display arc. The angle setter includes one or more pins and one or more fasteners to secure the angle setter to the respective surfaces of the two or more modular units. The angle setter is a component of an interconnecting sub-system of the modular display system.

The present application is related to the following listed application(s) (the “Related Applications”). All subject matter of the Related Applications and of any and all parent, grandparent, great-grandparent, etc. applications of the Related Applications is incorporated herein by reference in its entirety and to the extent such subject matter is not inconsistent herewith.

### RELATED APPLICATIONS

The present application is related to U.S. patent application Ser. No. 15/200,643, entitled MODULAR INTERLOCKING DISPLAY SYSTEM, naming Aaron D. Cass as inventor, filed Jul. 1, 2016. The present application claims priority to U.S. Provisional Application No. 62/361,831, entitled ANGLE SETTERS FOR ESTABLISHING DISPLAY PANEL CURVATURE, naming Aaron D. Cass as inventor, filed Jul. 13, 2016.

### BACKGROUND

Some modular display systems provide visual variety to a display experience. However, current systems are often limited in their ability to maximize deliverable visual variety. For example, current modular display panel systems are often limited by flat, rectilinear modular units.

Current improvements to existing personal HDTVs that provide a curved viewing experience, may increase viewer immersion by engaging peripherals, may increase viewer focus by conforming more to the shape of the eye, and may increase viewer perception by improving the direction of emitted light. Although many of these and other improvements are desirable as applied to modular display systems, opportunities for curved, large-scale modular display systems are limited or non-existent.

Therefore, it is desirous to obtain or otherwise improve upon modular display systems, methods, and/or apparatuses to provide improvements to a viewer's visual experience by enabling a curved, large-scale modular display system.

### SUMMARY

In one aspect, the inventive concepts disclosed herein are directed to an angle setter apparatus for establishing curvature for a modular display system. The angle setter apparatus may include an angled support having a first side, a second side, and a predetermined angle. The predetermined angle may be proportional to an angle of separation between two or more modular units of a modular display system. The angled support may include one or more alignment pins protruding from the first side of the angled support. The angled support may include one or more fasteners configured to be accessed from the second side of the angled support in order to couple the first side of the angled support to a surface of a first modular unit of the modular display system and to a surface of a second modular unit of the modular display system. The angle setter may link the first modular unit and the second modular unit together the first modular unit and the second modular unit are linked together to provide an overall angle or an overall curvature to the modular display system.

In another aspect, the inventive concepts disclosed herein are directed to a system for providing an angle of curvature for a modular display system. The system may include multiple modular units and an interlocking sub-system, the multiple modular units may be interconnected or interlocked by the interlocking sub-system to form a modular display system. The interlocking sub-system may include one or more angle setters, an alignment bar, and a channel. The one or more angle setters may be configured to provide a predetermined angle for enabling or providing curvature to the modular display system. The channel may be configured to receive the alignment bar and allow the alignment bar to rotate or move as two or more modular units are separated to enable or provide the predetermined angle to the modular display system.

In another aspect, the inventive concepts disclosed herein are directed to a modular display system with an angle of curvature. The modular display system includes a modular support frame with one or more modular units. The modular display system includes an interlocking sub-system. The interlocking sub-system may include one or more angle setters for providing the angle of curvature to a modular display system according to a predetermined angle. The modular display system further includes a power supply and a display panel. The display panel may include one or more modular units, and may be configured to interface with the power supply and a controller to receive power and display input. Two or more modular units of the modular support frame or two or more modular units of the display panel may be coupled together using the interlocking sub-system to form the modular display system.

### BRIEF DESCRIPTION OF THE DRAWINGS

Implementations of the inventive concepts disclosed herein may be better understood when consideration is given to the following detailed description thereof. Such description makes reference to the included drawings, which are not necessarily to scale, and in which some features may be exaggerated and some features may be omitted or may be represented schematically in the interest of clarity. Like reference numerals in the drawings may represent and refer to the same or similar element, feature, or function. In the drawings:

FIG. 1 shows a block diagram of a modular display system, according to the inventive concepts of the present disclosure;

FIG. 2 shows a back perspective view of an embodiment of two modular display units with angle setters, according to the inventive concepts of the present disclosure;

FIG. 3 shows a top view of a block diagram of modular display units and angles, according to the inventive concepts of the present disclosure;

FIG. 4 shows a back partial perspective view of an embodiment of two modular display units with angle setters, according to the inventive concepts of the present disclosure;

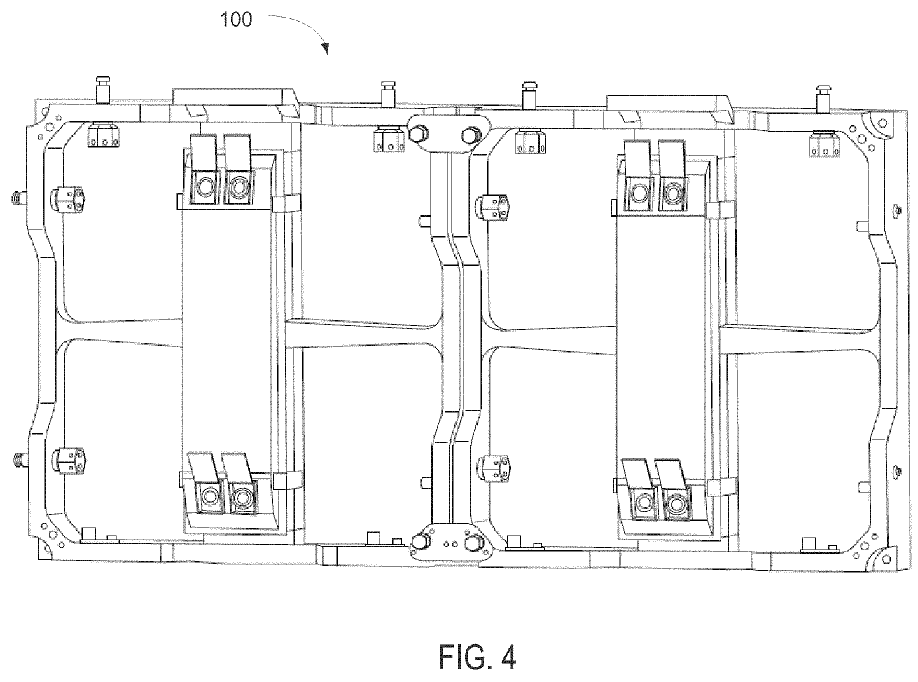

FIG. 5 shows a front perspective view of an embodiment of two modular display units with angle setters, according to the inventive concepts of the present disclosure;

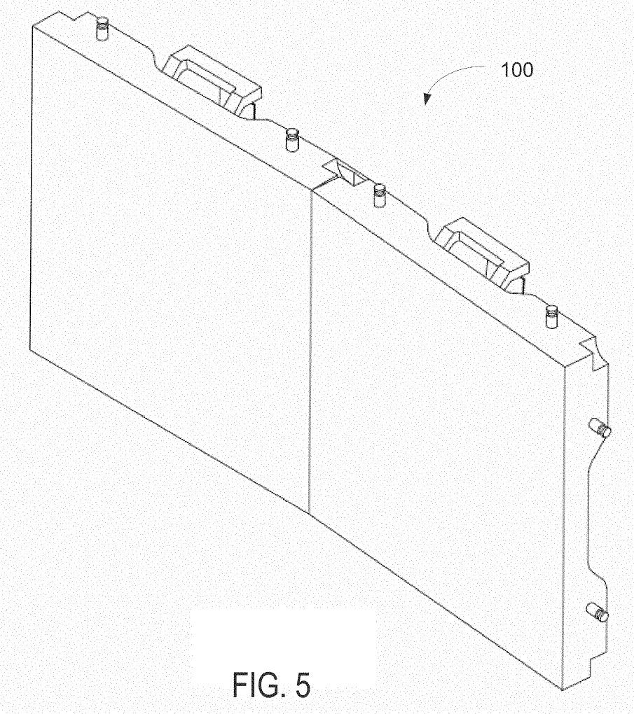

FIG. 6 shows a top view of an embodiment of two modular display units with angle setters, according to the inventive concepts of the present disclosure;

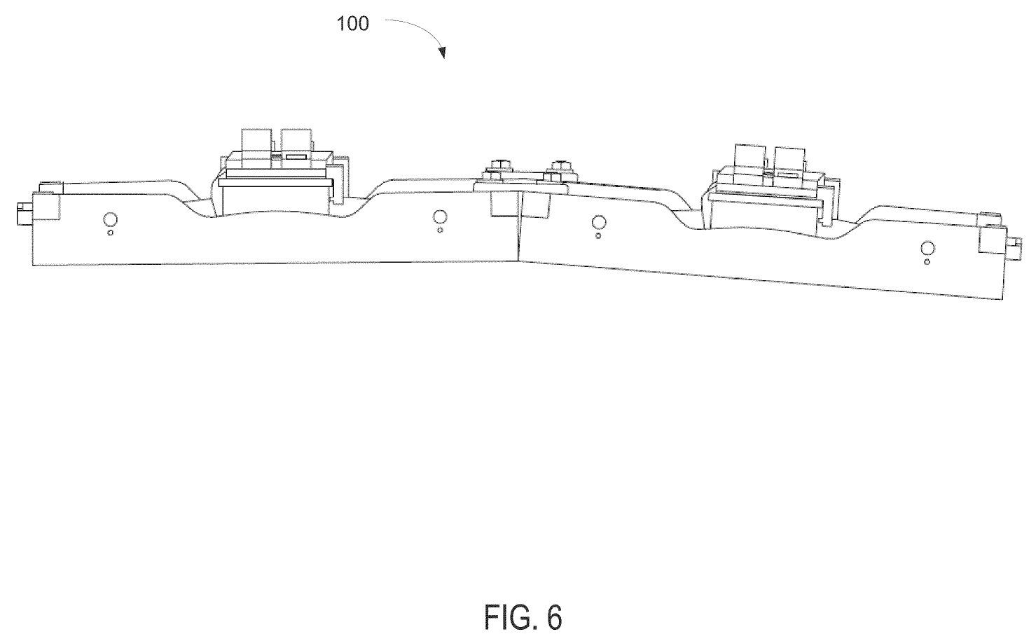

FIG. 7 shows a front perspective view of an embodiment of an angle setter, according to the inventive concepts of the present disclosure;

FIG. 8 shows a front view of an embodiment of an angle setter, according to the inventive concepts of the present disclosure;

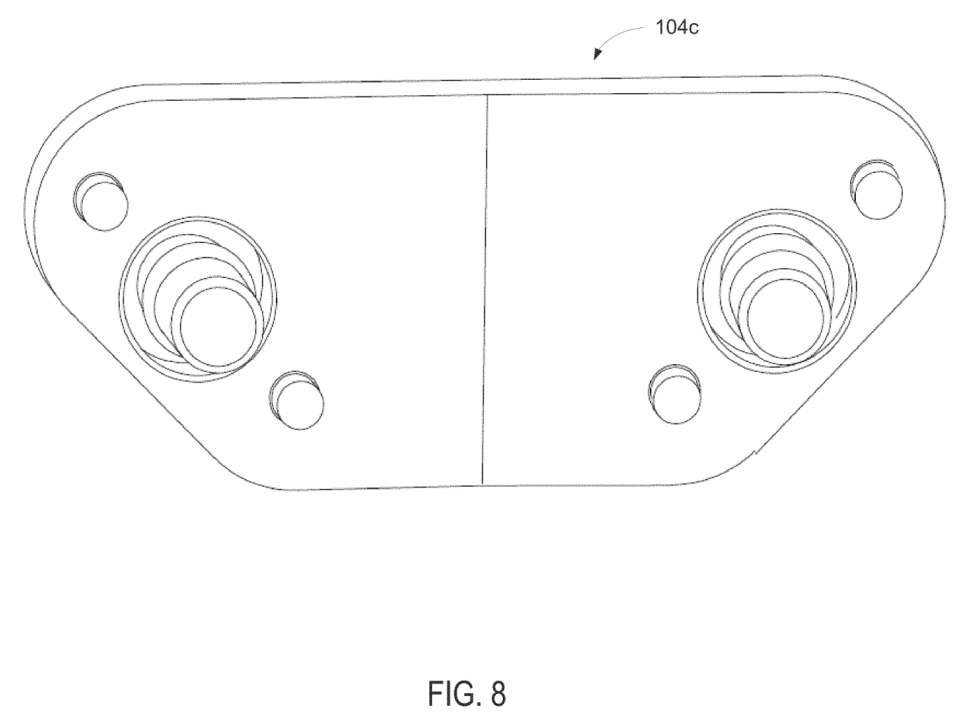

FIG. 9 shows a back perspective view of an embodiment of an angle setter, according to the inventive concepts of the present disclosure; and

FIG. 10 shows a back perspective view of an embodiment of two modular display units with an angle setter, according to the inventive concepts of the present disclosure.

### DETAILED DESCRIPTION OF EXEMPLARY EMBODIMENTS

Before explaining at least one embodiment of the inventive concepts disclosed herein in detail, it is to be understood that the inventive concepts are not limited in their application to the details of construction and the arrangement of the components or steps or methodologies set forth in the following description or illustrated in the drawings. In the following detailed description of embodiments of the instant inventive concepts, numerous specific details are set forth in order to provide a more thorough understanding of the inventive concepts. However, it will be apparent to one of ordinary skill in the art having the benefit of the instant disclosure that the inventive concepts disclosed herein may be practiced without these specific details. In other instances, well-known features may not be described in detail to avoid unnecessarily complicating the instant disclosure. The inventive concepts disclosed herein are capable of other embodiments or of being practiced or carried out in various ways. Also, it is to be understood that the phraseology and terminology employed herein is for the purpose of description and is not meant to be limiting.

Further, unless expressly stated to the contrary, “or” refers to an inclusive or and not to an exclusive or. For example, a condition A or B is satisfied by anyone of the following: A is true (or present) and B is false (or not present), A is false (or not present) and B is true (or present), and both A and B are true (or present).

Reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

“Large-scale” as used herein with respect to a display system means multiple (e.g., two or more) display units linked together to form a single display system.

“Small-scale” as used herein means a single modular display unit, or less (e.g., one or more display panels that are not a part of a group of display panels) to form a separate visual aspect of a modular interlocking display system.

Broadly, interlocking systems, methods, and apparatuses are disclosed for providing an angle or a curvature to a modular display system. In an exemplary embodiment, the interlocking system is designed for both small- and large-scale use, and is configurable to enable almost any visual arrangement for a modular display system. The desired angle or curvature of the system may be supplied by one or more angle setters, enabling in-part a convex curvature, a concave curvature, an obtuse angle, or an acute angle of the modular display system. The curved or angled viewing experience, may increase viewer immersion by engaging peripherals, may increase viewer focus by conforming more to the shape of the eye, or may increase viewer perception by improving the direction of emitted light. In this regard, support frames of display panels or segments of a segmented display panel may be separated, and when the emissive portion of the display panel is flexible, slight curvature is obtained. When separate display panels are incorporated on respective separated portions, then an angled display system is obtained.

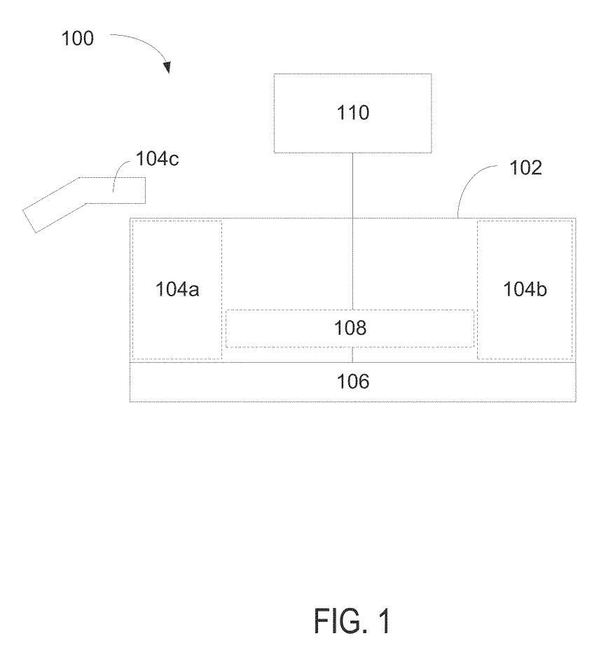

Referring now to FIG. 1, a block diagram of a modular display system 100 is depicted. In an exemplary embodiment, system 100 may include a modular support frame 102, an interlocking sub-system 104, one or more display panels 106, one or more interfaces (e.g., power supply, data input/output, etc.) 108, and a controller 110 communicatively coupled with the one or more interfaces 108.

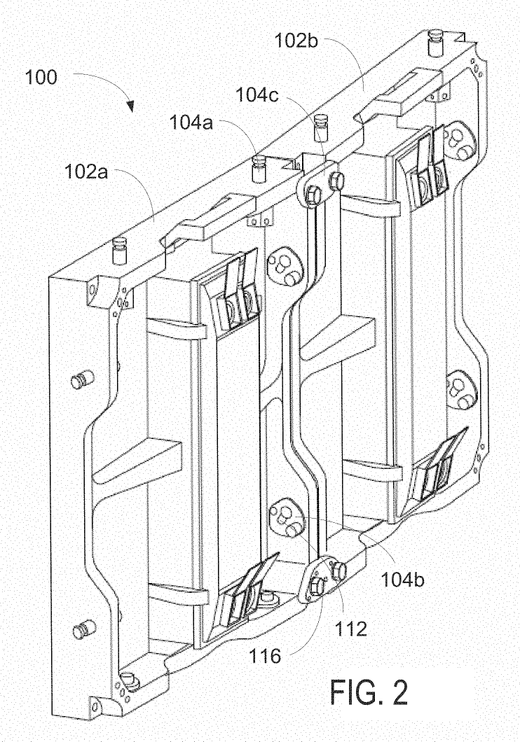

Referring now to FIG. 2, a more detailed perspective view of system 100 is depicted. The system 100 may include two modular units 102a and 102b separated according to an acute angle to provide an overall obtuse angle to the modular display system 100. It is noted that the overall obtuse angle of the system 100 depicted in FIG. 1 is not limiting, as the system 100 could be depicted as having an acute angle, a concave curvature, or a convex curvature, each of which is intended to be encompassed by the inventive concepts of the present disclosure.

In an exemplary embodiment, the display panel 106 includes a light emitting diode (e.g., LED or OLED) display panel. In other embodiments, other display panels may be used including, but not limited to, a liquid crystal display (LCD) panel.

In embodiments, the display panel 106 includes a single flexible display panel (e.g., organic light emitting diode (OLED) or other flexible panel material) that spans two modular units. The single flexible display panel may be flexed according to a desired amount of curvature or according to an angle of separation between separated modular units. For example, the angle of separation may be a small or slight separation and may be from a range of angles of separation, including, but not limited to, from 0.5° to 2.5° or from 2.5° to 5.0° degrees of separation, inclusive. It is noted that in some embodiments, almost any angle or any angle of separation may be achievable.

In other embodiments, the display panel 106 includes multiple display panels to span a single modular support unit (e.g., 102a), each of which may be slightly separated to provide one or more angles to the modular display system 100 and may be configured to be viewed as a single display. For example, referring again to FIG. 2, the two modular units 102a and 102b may be support frames that are slightly separated and each modular unit may have its own display panel 106 that is configured with controller 110 such that when viewed, a viewer sees each of the multiple panels as a single panel despite the slight angle existing between respective display panels of the multiple display panels.

In some embodiments, the display panel 106 includes multiple segments to form a segmented display panel providing additional benefits that come from another degree of modularity. For example, each segment of the segmented display panel may be hot-swappable.

In an exemplary embodiment, the display panel 106 may include a display panel that is modified or retrofitted according to the inventive concepts disclosed herein. For example, a display panel may include one of an LCD, LED, OLED, or other known display panel known in the art that has holes formed in a support structure of the display panel to coincide with one or more fasteners, pins, or connection points (e.g., mounts, brackets, screws, bolts, threaded holes, etc.) of the interlocking sub-system 104.

In an exemplary embodiment, the display panel 106 includes a weather-proof panel. For example, an embodiment of the modular panels may be rated with an Ingress Protection Marking, or IP Code rating, of IP65 (e.g., from any direction rated at IP65).

In an exemplary embodiment, a display panel 106 may be sized to cover multiple modular units. For example, the display panel 106 may include a first half of support portion (e.g., 102a, below), a second half of a support portion (102b, below), and a flexible LED tile positioned on a front surface of the support portions, may cover the entire surface (e.g., covers both the first half and the second half).

In an exemplary embodiment, the number of pixels within an LED tile of a display panel 106 may vary. For example, the number of pixels may include from 128×32, 96×24, 64×16 and/or 48×12 (e.g., with pixel densities respectively including 11,377 pix/sqm, 6,400 pix/sqm, 2,844 pix/sqm, and 1,600 pix/sqm).

In an exemplary embodiment, the controller 110 utilizes a first one or more communication links to communicate information to display panel 106 by way of the one or more interfaces 108. For example, the first one or more communication links may include an electrical, an optical, a wired, or a wireless communication link, and combinations thereof. In this regard, the one or more interfaces 108 may include a user input device, a display driver, a data link, or a bi-directional port, and combinations thereof, to relay information such as user input or rendering information to the display panel 106. The controller 110 may utilize a second one or more communication links to connect the controller and the I/O interface(s) to a network, including but not limited to, a Local Area Networks (LAN) (e.g., an Ethernet or corporate network), a Wide Area Network (WAN) (e.g., the Internet), a wireless data network, a fiber optical network, a radio frequency communications network, another electronic data network, or combinations thereof.

Referring again to FIG. 2, the modular support frame 102 may include a first modular unit 102a and a second modular unit 102b that are interconnected via the interlocking sub-system 104 to form the modular support frame 102. In embodiments, the modular support frame 102 may be made up of one or more of a rigid, semi-rigid, and flexible material. For example, the modular units 102a and 102b may be made up of the rigid material, which may be designed for light-weight, high-tensile strength. For instance, the rigid material may include, but is not limited to, A356 T6 aluminum, A201 T7 aluminum, A295 T6 or T62 aluminum, A328 T6 aluminum, A355 T71 aluminum, A771 T71 aluminum, other aluminum alloys, magnesium alloys, titanium alloys, beryllium alloys, carbon fiber materials (e.g., carbon fibers derived from polyacrylonitrile (PAN), reinforced carbon carbon (RCC), carbon-fiber-reinforced polymer (CFRP), carbon-fiber-reinforced plastic (CRP), carbon-fiber-reinforced thermoplastic (CFRTP), or combinations thereof), or combinations thereof.

In embodiments, the interlocking sub-system 104 includes an alignment bar 104a and an alignment plate 104b. The alignment bar 104a may be configured to be received by an alignment plate (not shown) of another modular support frame and the alignment bar plate 104b may be configured to receive an alignment bar (not shown) of another modular support frame.

In embodiments, the alignment bar 104a may be flanged and may include multiple alignment bars. In some embodiments, the multiple alignment bars include at least a first alignment bar that is orthogonal to a second alignment bar.

In embodiments, the alignment plate 104b may be channeled to allow movement of the alignment bar 104a in the channel. For example, a channel 112 of the alignment plate 104b may be curved to allow for movement of the flange of the alignment bar 104a along the channel according to a desired angle of separation between modular units of system 100. For instance, the modular units 102a and 102b may be initially interconnected without any curvature, or substantially in a flat or straight-lined configuration, but when the two modular units 102a and 102 are slightly separated along a vertical connection line at the back of the system 100, the curved channel 112 may allow for the alignment bar 104a to move to provide the slight separation according to the desired separation angle of system 100.

In some embodiments, the alignment plate 104b is formed with a hole therein in communication with the channel 112. The hole may be slightly larger than the flange of the flanged alignment bar 104a in order to allow insertion of the flanged alignment bar 104a into the channeled plate 104b.

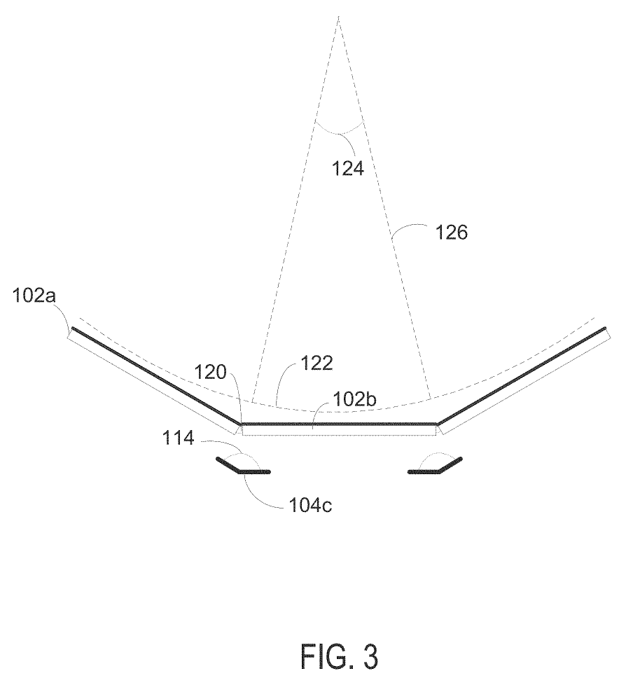

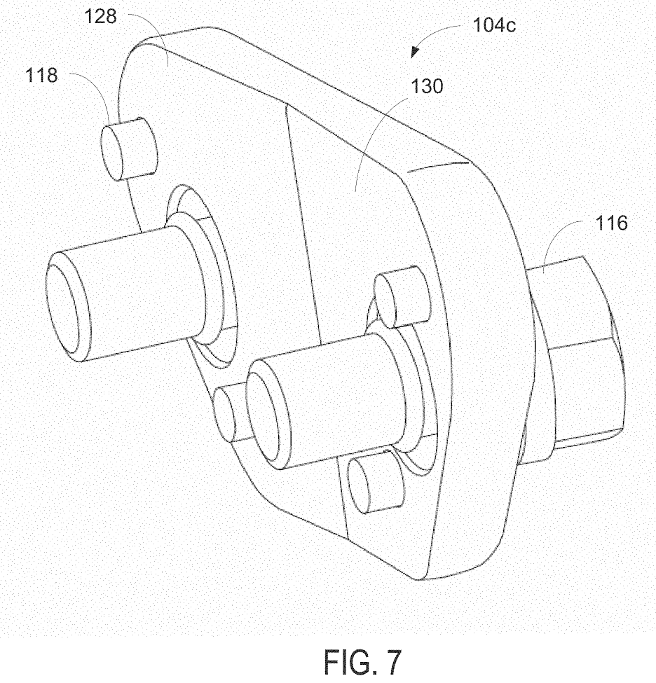

In an exemplary embodiment, the interlocking sub-system 104 includes an angle setter 104c. Referring now to FIGS. 2 and 3, the angle setter 104c may have a predetermined shape including a predetermined angle, psi (ψ) 114, and may be integrated with the modular units 102a and 102b of system 100. For example, the angle setter 104c may be coupled to each of the two modular units 102a and 102b using one or more fasteners 116 and one or more co-located alignment pins 118 (see FIG. 7). In some embodiments, fasteners 116 and the pins 118 are co-located with respect to a surface of the angle setter 104c from which they protrude, they are co-located with respect to a modular unit (e.g., 102b) with which they interface, or combinations thereof. For example, a first set of pins may be co-located on a first surface of the angle setter 104c and a second set of pins may be co-located on a second surface. The first set and the second set of pins 118 may be symmetrically separated from each other on a first side of the angle setter 104c.

In some embodiments, the angle, psi (ψ) 114, of the angle setter 104c may depend on, or at least be proportional to, an angle of separation, phi (Φ) 120, between modular units. For example, if the angle setter 104c has an angle, psi (ψ) 114, then an angle of separation between one or more modular units, phi (Φ) 120, may be related according to the following:

Φ≈180−ψ (1)

In some embodiments, the angle, psi (ψ) 114, of the angle setter 104c may depend on, or at least be proportional to, a display arc 122, or its center angle, theta (θ) 124, and a radius of curvature 126. For example, the desired center angle 124 of the display arc 122 (e.g., theta (θ)), may be related to the radius of curvature 126 according to the following:

L≈2R cos(½θ) (2)

L≈\sqrt{2a²−2a² cos(180−Φ)} (3)

such that when an operator decides on the desired radius of curvature 126 and/or the desired center angle 124 of the display arc 122, then one can solve for L using relationship (2), and thereby solve for phi (Φ) 120 and psi (ψ) 114 using relationships (1) and (3). It is noted that the display arc 122 may represent an arc that approximates a viewer experience of display system 100 resulting from interconnected modular units (e.g., segmented display panels or support frames).

In other embodiments, the angle, psi (ψ) 114, may depend on, or at least be proportional to, a desired angle, omega (ω) that is proportional to a number of modular units, N, used in assembling the modular display system 100. For example, if the desired shape of the display system 100, at least with respect to interconnected frames 102, resembles that of a polygon or a portion of a polygon, then the angle, omega (ω), may be proportional to N modular display units (e.g., support frames 102), where N is greater than two, as follows:

$$\begin{matrix}ω \approx \frac{( N - 2 ) \times 180 °}{N} & ( 4 ) \\ ψ \approx 180 - ω & ( 5 )\end{matrix}$$

In some embodiments, the angle omega (ω) may be proportional to, or substantially equivalent to, the separation angle, phi (Φ) 120.

In an exemplary embodiment, the angle, psi (ψ) 114 of the angle setter 104c may be created by machining a rigid support, a rigid bracket, or a rigid brace (e.g., via facial milling) to have one or more portions removed from a side of the rigid support to create the angle. For example, referring now to FIG. 7, a first facial portion may be milled to remove first material and create the slope of surface 128, and a second facial portion may be milled to remove second material and create the slope of surface 130. It is noted that in some embodiments, the milling of surfaces 128 and 130 may occur simultaneously.

In an exemplary embodiment, the one or more fasteners 116 and the one or more pins 118 of the angle setter 104c may be orthogonal to a plane of a surface from which they protrude. In this regard, the angle setter 104c may include at least two surfaces that have equal but opposite (e.g., opposite in sign) slopes. For instance, the angle setter 104c of FIG. 7 depicts a first surface 128 on a first side of the angle setter 104c that has a first slope and a second surface 130 on the same side that has a second slope, where the second slope is equal but opposite to the first slope.

In an exemplary embodiment the one or more fasteners 116 include multiple fasteners (e.g., two), and the one or more pins 118 includes multiple pins (e.g., four).

In some embodiments, the angle, psi (ψ) 114 of the angle setter 104c may be formed by forming a line along a center-axis of a facial surface of the rigid support and bending each side of the rigid support along the line to create the angle. For example, the line may be cut, scored, etched, or otherwise formed in the facial surface. In this regard, the line may form a trough having two sloping or angled sides, where the bending is permitted until the two sloping or angled sides meet.

In some embodiments, the angle setter 104c may be made up of two or more materials. The first material being a rigid material comprising steel, aluminum, carbon fiber, a rigid polymer-based fiber, a metal alloy, or combinations thereof, to create a back-support for the angle setter 104c. The second material may be rigid, semi-rigid (epoxy-based), or flexible (e.g., rubber, elastomer, elastomeric polymer, etc.), and may be molded, cast, or otherwise formed onto the back-support to create, provide in-part, or enable the angle of the angle setter 104c. In other embodiments, the flexible material may be formed onto the back-support to increase protection, increase gripping, or reduce slipping between surfaces of the angle setter 104c and surfaces of a modular unit.

In embodiments, the angle setter 104c may be of different sizes and/or angles depending on a location for which it is intended for use within the modular display system 100. For example, a first set (e.g., two or more) of angle setters 104c may be used to connect two or more segments of a segmented display panel 106, where each segment is a modular unit. By way of another example, a second set of angle setters 104c may be used to connect two support frames, where each of the two support frames is a modular unit. By way of yet another example, the first and second sets may be used in combination with each other to provide a modular display system that incorporates angled segmented display panels and angled support frames interconnected by the angle setter 104c. In this regard, if a first angle setter 104c of the first set is intended to be used to establish an angle of the segmented display panel, then it may have a relatively small size such that it may be integrated with a panel having combined dimensions of 100 mm×500 mm (e.g., a first half of the panel may be 100 mm×250 mm and a second half of the panel may be 100 mm×250 mm). If a second angle setter 104c of the second set is intended to be used to connect two or more support frames (e.g., each frame having a size of 1000 mm×1000 mm×145 mm), then a size of the second angle setter may be relatively larger than the first angle setter. Because embodiments may vary in sizes, exemplary embodiments disclosed herein may maintain a width to height ratio of the angle setter 104c. For example, the width to height ratio may include a ratio of approximately 1:2.

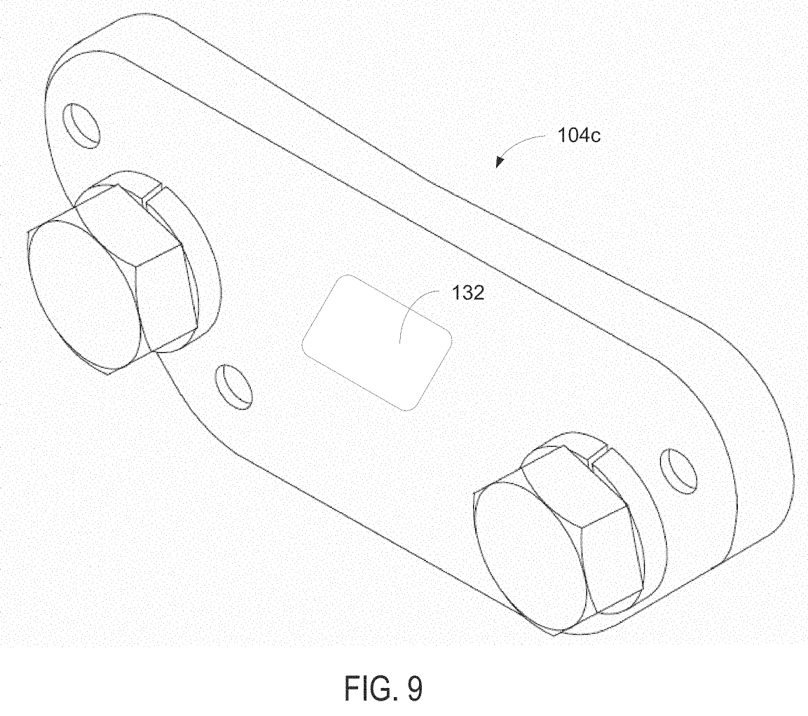

In some embodiments, because a size and/or angle of the angle setter 104c may vary depending on where it is intended to be used in the system 100, in some embodiments the angle setter 104c may include an identifier 132. The identifier 132 may include an imprinted number or label formed in the angle setter 104c, where the imprinted number or label may include at least the angle psi (ψ) 114 of the angle setter 104c. For example, referring now to FIG. 9, an angle setter 104c is depicted with an identifier 132 to indicate a 5.0 degree angle corresponding to the angle of the angle setter 104c. It is noted that although the identifier 132 is depicted as being associated with an exterior surface of the angle setter 104c, other locations for the identifier 132 are contemplated herein. In this regard, the identifier 132 may be associated with an interior or front surface, a side surface, a top surface, a bottom surface, or combinations thereof.

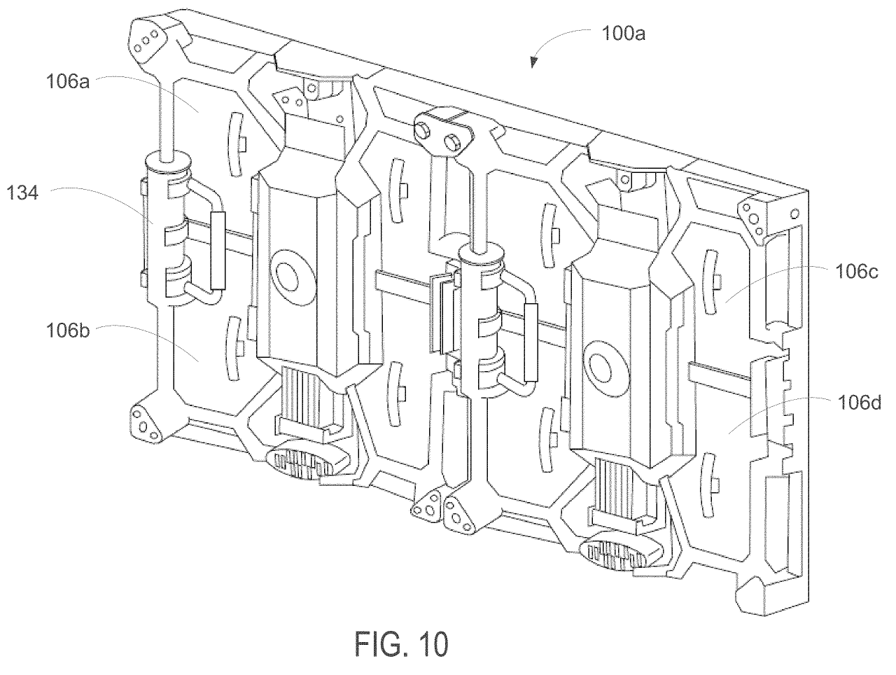

In some embodiments, the interlocking sub-system 104 includes a bar and hooking configuration 134. For example, referring now to FIG. 10, the system 100a may function similarly to system 100 except that system 100a may include the bar and hooking configuration for interlocking modular units and except that system 100a may include multiple display panel segments/portions 106a-106d, with each display panel segment/portion 106a-106d having a handle for ease of removal or replacement of the respective display panel segment/portion. For instance, each display panel segment/portion 106a-106d may be hot-swappable. In some embodiments, the bar and hooking configuration 134 is used to interconnect or couple a first modular support unit including a first segmented display panel to a second modular support unit including a second segmented display panel.

In embodiments, the controller 110 is in communication with, or implemented within a computer. The computer may include one or more processors (e.g., field programmable gate array (FPGA), microprocessor, application specific integrated circuit (ASIC), etc.) and one or more memories (e.g., non-transitory memory, solid state memory, disc memory, or combinations thereof) with instructions thereon for performing one or more processes disclosed herein.

It is noted that although FIGS. 1 and 10 depict specific modular configurations of system 100 and system 100a, other modular configurations are contemplated and encompassed by the inventive concepts of the present disclosure. For example, FIG. 1 depicts a modularity that includes a modular unit corresponding with single display panel support frames (e.g., 102a and 102b) and includes a large-scale modularity that corresponds with two or more interlocked support frames (e.g., 102a and 102b). It is further noted that this depiction is merely for illustrative purposes. By way of another example, a modularity may include a segmented display panel such that a modular unit includes two segments of the display panel interconnected by a small or small-scale angle setter 104c. Those skilled in the art will recognize other modularity configurations corresponding to the inventive concepts disclosed herein, each of which are intended to be encompassed.

In embodiments, the support portion (e.g., support frame 102) of system 100 may include multiple similar, if not identical (e.g., for ease of manufacturing), support modular units. In some embodiments, the near-identical support modular units are support halves. In other embodiments, the near-identical support modular units may include more than two halves (e.g., may include three, four, or more support segments, etc.) with an input/output (I/O) port located on each segment of the multiple support segments. In other embodiments, only two segments of the support segments have I/O ports located thereon. In some embodiments, only one support modular unit of the multiple support modular units includes an I/O port, and the multiple support segments may be interconnected with wires, or other electronic communication means.

It is to be understood that embodiments of the methods according to the inventive concepts disclosed herein may include one or more of the steps described herein. Further, such steps may be carried out in any desired order and two or more of the steps may be carried out simultaneously with one another. Two or more of the steps disclosed herein may be combined in a single step, and in some embodiments, one or more of the steps may be carried out as two or more sub-steps. Further, other steps or sub-steps may be carried in addition to, or as substitutes to one or more of the steps disclosed herein.

From the above description, it is clear that the inventive concepts disclosed herein are well adapted to carry out the objects and to attain the advantages mentioned herein as well as those inherent in the inventive concepts disclosed herein. While presently preferred embodiments of the inventive concepts disclosed herein have been described for purposes of this disclosure, it will be understood that numerous changes may be made which will readily suggest themselves to those skilled in the art and which are accomplished within the broad scope and coverage of the inventive concepts disclosed and claimed herein.

What is claimed:

1. A modular display system with an angle of curvature, comprising:
a modular support frame comprising one or more modular units;
an interlocking sub-system comprising one or more angle setters for providing the angle of curvature to a modular display system according to a predetermined angle;
a power supply; and
a display panel comprising one or more modular units, the display panel configured to interface with the power supply and a controller to receive power and display input, wherein two or more modular units of the modular support frame or of the display panel are coupled together using the interlocking sub-system to form the modular display system.

2. The system of claim 1, wherein the display panel comprises a segmented display panel with each segment of the segmented display panel comprising a modular unit of the one or more modular units of the display panel.

3. The system of claim 2, wherein at least two or more segments of the segmented display panel has an angle setter coupled to a surface of a first segment and a surface of a second segment of the segmented display panel.

4. The system of claim 1, wherein the predetermined angle is proportional to a separation angle, the separation angle being between two or more modular units of the modular support frame or between two or more modular units of the display panel.

5. The system of claim 1, wherein the predetermined angle is proportional to a display arc and a radius of curvature.

6. The system of claim 5, wherein the predetermined angle is proportional to the display arc and the radius of curvature according to one or more of a plurality of relationships, the plurality of relationships comprising: L≈2R cos(½θ); L≈\sqrt{2a²−2a² cos(180−Φ)}; and Φ≈180−ψ, wherein L is a chord length of the display arc, a is a width of a modular unit of the support frame, R is the radius of curvature, phi is an angle of separation, theta is a center angle of the display arc, and psi is the predetermined angle.

7. The system of claim 1, wherein the interlocking sub-system further comprises a flanged alignment bar and a curved channel, the flanged alignment bar being attached to a first support frame and the curved channel being integrated with a second support frame.

8. The system of claim 7, wherein the first support frame and the second support frame are linked together using the angled support and further using the flanged alignment bar, the linking occurring as the flanged alignment bar is received and moved within the curved channel and the angled support being aligned with and secured to the first support frame and the second support frame.

9. The system of claim 1, wherein the interlocking sub-system further comprises a bar and hooking configuration for interconnecting the two or more modular units of the modular support frame.

10. An angle setter apparatus for establishing curvature for a modular display system, comprising:
an angled support having a first side, a second side, and a predetermined angle, the predetermined angle being proportional to an angle of separation between two or more modular units of a modular display system;
one or more alignment pins protruding from the first side of the angled support; and
one or more fasteners configured to be accessed from the second side to couple the first side of the angled support to a surface of a first modular unit of the modular display system and to a surface of a second modular unit of the modular display system, wherein the first modular unit and the second modular unit are linked together to provide an overall angle or an overall curvature to the modular display system.

11. The apparatus of claim 10, wherein the angle of separation comprises a range of angles, wherein the range of angles comprises at least one of: from 0.5° to 2.5° and from 2.5° to 5°.

12. The apparatus of claim 10, wherein the angled support comprises one of a rigid material, a semi-rigid material, and a flexible material.

13. The apparatus of claim 12, wherein the angled support comprises the rigid material and is facially milled to provide a first surface with a first slope and a second surface with a second slope, the first and second slopes forming the predetermined angle.

14. The apparatus of claim 10, wherein a size of the angle setter apparatus comprises a width to height ratio of 1:2.

15. The apparatus of claim 10, wherein the angle of separation is related or proportional to a desired radius of curvature, a center angle of a display arc, or a desired angle of curvature of the modular display system.

16. The apparatus of claim 10, further comprising an identifier to provide the predetermined angle to an operator or user.

17. An angle setter, comprising:
a support including a first side, a second side, a first surface with a first slope, and a second surface with a second slope, the first surface and the second surface being located on the first side of the support;
a plurality of alignment pins protruding from the first side of the support; and
one or more fasteners accessible from the second side of the rigid support to secure a first modular unit together with a second modular unit, the first and second modular units secured to form a modular display system.

18. The angle setter of claim 17, wherein the first slope and the second slope form a predetermined angle, the predetermined angle being proportional to at least one of: a number of modular units of the modular display system, a display arc, a center angle of the display arc, and a radius of curvature.

19. The angle setter of claim 17, wherein the first slope and second slope are formed by machining or milling the first side of the rigid support.

20. The angle setter of claim 17, wherein the plurality of alignment pins and the one or more fasteners are orthogonal to the first surface or the second surface.

21. The angle setter of claim 17, wherein the rigid support comprises at least two materials, a first material forming a back-support and the second material being molded cast, or formed onto the back support to provide or maintain the first slope and the second slope.

22. The angle setter of claim 21, wherein the first material is a rigid material and the second material is a semi-rigid material or a flexible material.

23. The angle setter of claim 17, wherein the support comprises a brace for interconnecting and securing the first and second modular units to form the modular display system.

24. The angle setter of claim 17, wherein a first one or more pins of the plurality of pins and a first fastener of the one or more fasteners protrude or are located on the first surface of the support and a second one or more pins of the plurality of pins and a second fastener of the one or more fasteners are located on the second surface of the support.

25. A system for providing an angle of curvature for a modular display system, comprising:
a plurality of modular units; and
an interlocking sub-system, the plurality of modular units interconnected or interlocked by the interlocking sub-system to form a modular display system, the interlocking sub-system including one or more angle setters, an alignment bar, and an alignment plate with a channel,
the one or more angle setters being configured to provide a predetermined angle for enabling or providing curvature to the modular display system and the channel being configured to receive the alignment bar and allow the alignment bar to rotate or move as two or more modular units of the plurality of modular units are separated to enable or provide the predetermined angle to the modular display system.

26. The system of claim 25, wherein the plurality of modular units comprises one of two or more modular support frames and two or more segments of a segmented display panel, and wherein the predetermined angle is proportional to a number of the plurality of modular units used to form the modular display system.

27. The system of claim 25, wherein the alignment bar comprises a flanged alignment bar and the channel comprises a curved channel.

28. The system of claim 25, wherein the two or more modular units comprises a first modular unit and a second modular unit, the first modular unit includes the flanged alignment bar and the second modular unit includes a curved channel, wherein the curved channel is configured to receive the flanged alignment bar and rotate as an angle setter of the one or more angle setters is secured the first modular unit and to the second modular unit according to the predetermined angle.
